(19) United States
(12) Patent Application Publication
(10) Pub. No.: US 2026/0338990 A1
(43) Pub. Date: Oct. 29, 2026

(54) Metalens for Polarization-Aware Bayer Imaging

(71) Applicant: Mitsubishi Electric Research Laboratories, Inc., Cambridge, MA (US)

(72) Inventors: Matthew Brand, Newton, MA (US); Hsin Pan, Princeton, NJ (US)

(73) Assignee: Mitsubishi Electric Research Laboratories, Inc., Cambridge, MA (US)

(21) Appl. No.: 19/187,229

(22) Filed: Apr. 23, 2025

(51) Int. Cl. G02B 1/00; H10F 39/00

(52) U.S. Cl. CPC G02B 1/002; H10F 39/806; G02B 2207/101

(57) ABSTRACT

A metalens including one or more layers of subwavelength nanostructures configured to redirect incident light onto a detector plane in a plurality of spatially distinct polarized Bayer patterns. Each polarized Bayer pattern may include at least four sensor pixels, each corresponding to a distinct combination of wavelength band and polarization state. At least two of the sensor pixels within each polarized Bayer pattern correspond to a common wavelength band but orthogonal linear polarization states.

### TECHNICAL FIELD

The present disclosure relates generally to the field of optics and photonic device engineering, and more specifically to metasurfaces and metalenses designed for multifunctional light manipulation. In particular, it pertains to the design and implementation of inverse-designed multilayer freeform metalenses capable of performing simultaneous wavelength (color) sorting and polarization sorting for use in imaging, sensing, and light-emitting applications.

### BACKGROUND

A metalens is a surface decorated with sub-wavelength scale structures that interact with an electromagnetic field. These sub-wavelength scale structures typically provide some optical function similar to a lens that can be used in systems such as cameras or medical equipment. Traditional camera systems rely on Bayer color filters and polarizing filters from an incident light field for image reconstruction, limiting energy utilization efficiency and sensitivity. To challenge these constraints, metalens-integrated systems incorporate sub-wavelength structures that reshape wavefronts, enabling enhanced image quality in lowlight conditions by “sorting” incident light by frequency or polarization.

The “inverse design” of a meta surface, which provides a desired optical function is quite challenging due to the enormous computational expense of simulation. The standard workaround is to limit the space of possible designs to a grid-tiling of the surface using a small set of pre-characterized structures, with no shape variation in the direction of propagation. The summed effect of these “meta surface atoms” is in some cases a good approximation of the actual effect of the device. This “unit cell decomposition” method can provide ease of design, at cost of reduced efficiency and efficacy. However, the dependence on atoms limits the ultimate efficiency of the design.

Current systems lack a metalens that is capable of high performance in areas such as color sorting and polarization sorting. These limitations can translate into reduced image quality and information accuracy, increased computational burden for correction or enhancement, barriers to deployment in high-performance or real-time systems, and more. Furthermore, color-sorting and color-filtering devices often have redundant green-channel elements.

Thus, there is a need for a high performing metalens that pushes performance in areas such as color sorting and polarization sorting.

### SUMMARY

Modern imaging systems typically rely on hardware components such as Bayer filter arrays and polarization filters to capture spectral (color) and polarization information from a scene. Each of these components independently filters a portion of the incoming light to extract one dimension of information—either wavelength or polarization state—while absorbing or discarding the rest. This modular approach leads to fundamental inefficiencies, particularly in low-light conditions or real-time applications where light throughput and compactness are at a premium.

Some embodiments presented herein are based on the recognition that color and polarization are orthogonal properties of light and, as such, can be sorted concurrently within the same optical structure. This recognition enables a radical departure from conventional designs by allowing both attributes to be extracted optically—without the need for separate filters or sequential exposures. Such functionality becomes increasingly advantageous in environments demanding compact, high-speed, and energy-efficient imaging systems.

To achieve this dual-functionality, some embodiments reimagine the Bayer cell not merely as a post-processing pattern or as a passive color filter, but as an optical element capable of redirecting light according to both wavelength and polarization. In these embodiments, each cell of the Bayer layout (typically configured as red, blue, and two green sub-pixels) corresponds to a spatially distinct region on a detector plane. These regions are engineered to separate and direct incident light of particular color and polarization states to appropriate designated pixels on the underlying image sensor.

For example, rather than configuring both green-channel pixels to capture semi-redundant green light information, some embodiments assign them to detect orthogonal polarization components—such as x- and y-polarized green light—thereby enabling polarization-resolved color imaging at the sensor level. Furthermore, these green-channel pixels can also receive green light that is incident on adjacent red-channel and blue-channel elements of the metalens. In this framework, the metalens Bayer cell no longer functions by filtering and blocking light; instead, it acts as a spatial light sorter, maximizing photon utilization and enabling the recovery of richer visual information from a single exposure.

This capability is made possible through the use of inverse-designed freeform metalenses, wherein subwavelength meta-structures are computationally optimized to redirect light with high efficiency. Traditional metasurface design relies on libraries of pre-characterized “meta-atoms”—geometric elements with fixed optical responses—but these are poorly suited to multifunctional tasks like simultaneous color and polarization sorting. Some embodiments therefore leverage freeform metasurfaces, where the structure is not constrained to periodic arrangements, and the geometry varies continuously to satisfy complex optical objectives.

The design of such devices involves a significantly larger parameter space, which poses challenges for conventional design workflows. Accordingly, some embodiments employ gradient-based inverse design techniques, such as those implemented in Finite-Difference Time-Domain (FDTD) solvers, to explore the design space efficiently. In particular, some embodiments use adjoint-based optimization to compute gradients with respect to performance objectives, enabling rapid refinement of metasurface geometries.

Recognizing that a single-layer metasurface may lack sufficient degrees of freedom to sort light by both color and polarization with high efficiency, some embodiments implement a multilayer architecture. In such configurations, a first layer is optimized to achieve a coarse approximation of the desired optical function, such as phase modulation for color separation. A second layer is then optimized to correct residual errors, enhance polarization discrimination, and fine-tune the overall far-field response.

Some embodiments proceed by pre-optimizing each layer independently according to its partial objective and then engaging in joint optimization, where the two layers are co-designed to work in synergy. This hierarchical design approach improves convergence behavior and increases the likelihood of achieving an optical structure with both high efficiency and low crosstalk between sorting channels.

By interpreting the Bayer filter not as a color filter array but as a spatially encoded metasurface, some embodiments achieve a physical structure in which light of different wavelengths and polarization states is routed to distinct pixels. This architecture replaces the light-blocking nature of conventional filters with a sorting-based mechanism, preserving energy and enabling single-exposure acquisition of full color and polarization information.

The resulting multilayer metasurface, in some embodiments, achieves average color sorting efficiencies of over 60% and polarization sorting efficiencies exceeding 50%, outperforming prior state-of-the-art solutions. The metasurface can be integrated directly atop a broadband image sensor, or within an optical stack that includes additional focusing or collimating elements, depending on the application.

These technical advancements are particularly beneficial in applications such as mobile imaging, robotic vision, and autonomous sensing, where size, power, and speed constraints rule out bulky polarization cameras or time-multiplexed solutions. By enabling polarization-aware Bayer imaging in a single optical layer—or bilayer—these embodiments reduce system complexity and allow more of the sensing and computation to be handled optically rather than digitally.

Altogether, the present disclosure introduces a novel interpretation and implementation of the Bayer cell through the use of single or multilayer, inverse-designed metalenses. This approach enables concurrent color and polarization sorting, offering a high-performance solution to longstanding limitations in imaging hardware.

### BRIEF DESCRIPTION OF THE DRAWINGS

Many aspects of the disclosure may be better understood with reference to the following drawings. The components in the drawings are not necessarily to scale, emphasis instead being placed upon clearly illustrating the principles of the present disclosure. Moreover, in the drawings, reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1A shows a schematic of the departure from a conventional imaging system to a proposed imaging system, according to some embodiments of the present disclosure.

FIG. 1B shows a schematic of a proposed imaging system, according to some embodiments of the present disclosure.

FIG. 1C shows a schematic of a polarized Bayer pattern, according to some embodiments of the present disclosure.

FIG. 2A shows a schematic of a metalens, according to embodiments of the present disclosure.

FIG. 2B shows a schematic of a bilayer metalens, according to some embodiments of the present disclosure.

FIG. 2C shows an optical configuration designed for simultaneous color and polarization sorting, according to some embodiments of the present disclosure.

FIG. 3A shows an overview of the optimization process for designing a metalens using electromagnetic simulation, according to some embodiments of the present disclosure.

FIG. 3B shows a diagram of an inverse design flowchart according to some embodiments of the present disclosure.

FIG. 4A shows a schematic of target phase profiles for red, green, and blue according to some embodiments.

FIG. 4B shows a schematic of an initial design, according to some embodiments.

FIG. 4C shows a cross-view section of an initial design, according to some embodiments.

FIG. 4D shows a schematic of optimized Bayer cells, according to some embodiments of the current disclosure.

FIG. 5 shows a color imaging experimental setup, according to some embodiments of the current disclosure.

FIG. 6A shows various focal plane intensities for a pixel illuminated by white light, according to some embodiments of the present disclosure.

FIG. 6B shows a table that summarizes a comparison of baseline metalenses to a proposed metalens, according to some embodiments of the present disclosure.

FIG. 6C shows a schematic of the full-color imaging of a metalens, according to some embodiments of the present disclosure.

FIG. 7 shows an example configuration of a computing module, according to embodiments of the present disclosure

FIG. 8 shows a diagram illustrating an overview of the manufacturing process, according to some embodiments of the present disclosure.

FIG. 9A shows a schematic of a patch of metalens, before and after freeform optimization, according to embodiments of the present disclosure.

FIG. 9B shows a flowchart with steps involved in optimizing freeform design, according to some embodiments of the present disclosure.

FIG. 9C shows a schematic of an optimization problem solved by some embodiments to improve the focal efficiency of a metalens with freeform topology, according to some embodiments of the present disclosure.

FIG. 9D shows a schematic of an optimization problem solved by some embodiments to improve the focal efficiency of a metalens topology, according to some embodiments of the present disclosure.

FIG. 9E shows a schematic of a patch of metalens before and after optimization according to an embodiment of the present disclosure.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a FIG. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

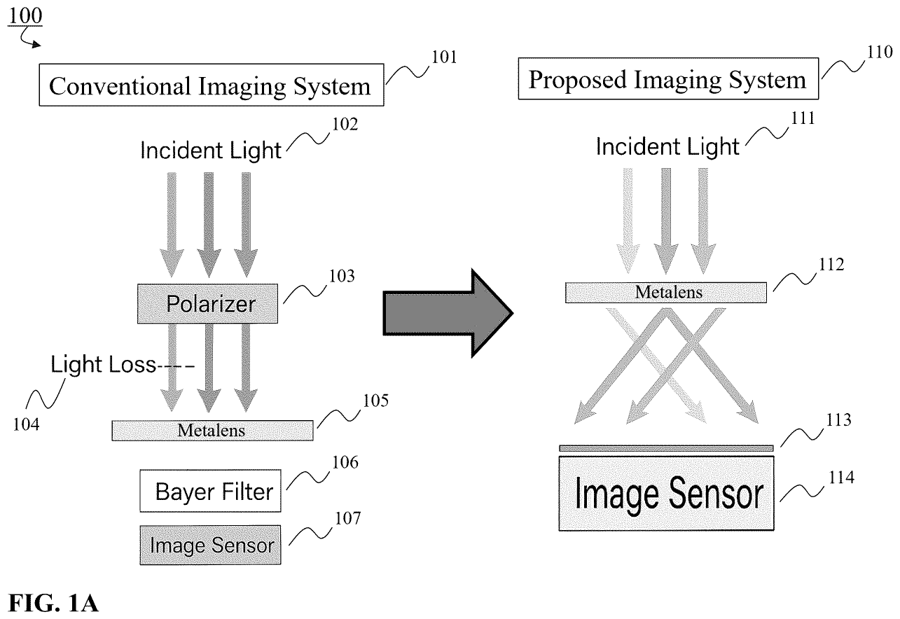

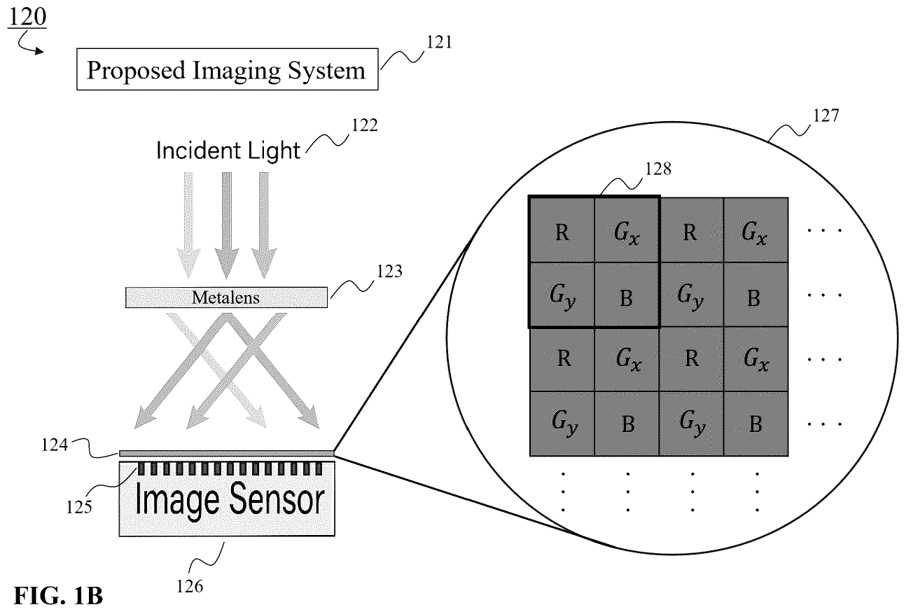

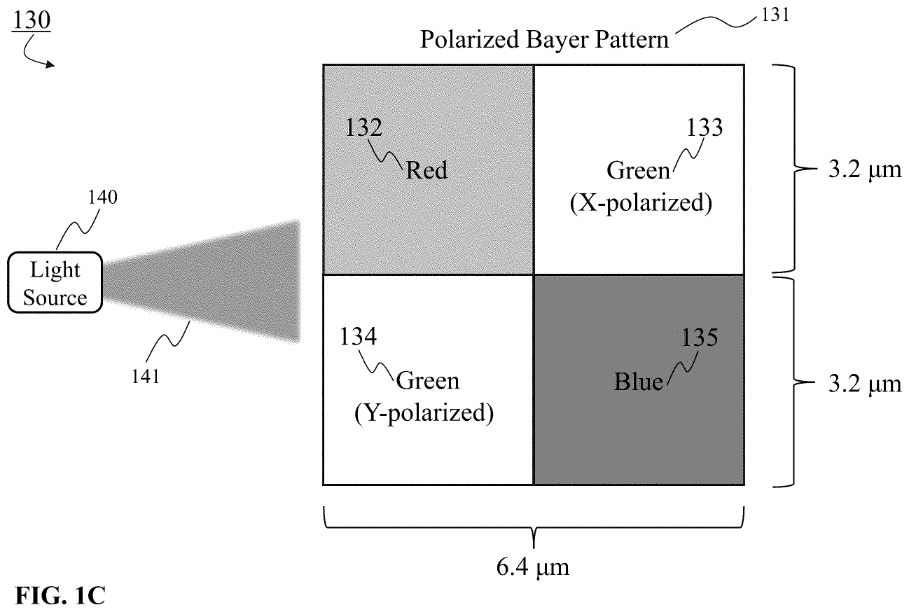

FIG. 1A shows a schematic 100 of the departure from a conventional imaging system 101 to a proposed imaging system 110, according to some embodiments of the present disclosure. A conventional imaging system 101 may be designed with the intention of polarization-aware, color-sensitive imaging using a metalens-based optical path. Incident light 102 from the scene or environment enters the convention imaging system 101. Polarizer 103 filters the incoming light to allow for a specific polarization state such as horizontal or vertical. Light loss 104 is typically associated with the use of polarizer 103, as light can be blocked, absorbed, or occur from surface reflections and material absorption. Then, metalens 105 can manipulate the phase of light to focus or direct it. In conventional imaging system 101, alternative lenses may be used in place of metalens 105, depending on the design task at hand. Bayer filter 106 on top of image sensor 107 allows each sensor pixel to capture one color, enabling color imaging when combined with demosaicing algorithms. However, the use of Bayer filter 106 causes significant light loss. Metalens 105 and polarizer 103 order can be swapped depending on the design task at hand. Ultimately, the approach of conventional imaging system 101 can lead to fundamental inefficiencies, particularly in low-light conditions or real-time applications where light throughput and compactness are at a premium.

In proposed imaging system 110, incident light 111 from the scene or environment enters the system. The light enters metalens 112, which is optimized for color and polarization sorting. The light exiting metalens 112 is arranged in Bayer patterns 113, which are configured to redirect incident light of a specified wavelength band and polarization state onto a corresponding sensor pixel of image sensor 114. Bayer patterns 113 are not necessarily a physically tangible component of proposed imaging system 110. Rather, Bayer patterns 113 are the result of spatial light sorting, maximizing photon utilization and enabling the recovery of richer visual information from a single exposure. The proposed imaging system 110 of FIG. 1A achieves both color and polarization sorting without the need for separate filters or sequential exposures present in conventional imaging system 101. Ultimately, the functionality of proposed imaging system 110 becomes increasingly advantageous in environments demanding compact, high-speed, and energy-efficient imaging systems.

FIG. 1B shows a schematic 120 of a proposed imaging system 121 according to some embodiments of the present disclosure. In proposed imaging system 121, incident light 122 from the scene or environment enters the system. The light enters metalens 123, which is optimized for color and polarization sorting. The light exiting metalens 123 is arranged in Bayer patterns 124. The top view 127 of Bayer patterns 124 shows an arrangement of pixels, each corresponding to a distinct combination of wavelength band and polarization state. The overall quantity of pixels can vary according to the design task at hand.

In the embodiment shown in FIG. 1B, the repeating Bayer pattern 128 features four pixels in an RGGB Bayer arrangement. “R” corresponds to a region configured to redirect red light onto a respective sensor pixel. “Gₓ” corresponds to a region configured to redirect green light having an X-polarization state onto a respective sensor pixel. “G_{y}” corresponds to a region configured to redirect green light having a Y-polarization state, orthogonal to “Gₓ”, onto a respective sensor pixel. “B” corresponds to a region configured to redirect blue light onto a respective sensor pixel.

In the exemplary embodiment of FIG. 1B, the image sensor 126 is made up of 1024×1024 pixels. Each pixel can be implemented by a sensor well 125 that absorbs photons and converts them into electric potential. In the embodiment of FIG. 1B, each pixel of the RGGB Bayer arrangement of Bayer pattern 128 is the same size as a sensor well. In this manner, Bayer pattern 128 is repeated to cover the entire image sensor. Ultimately, each of the regions of the Bayer pattern are configured to redirect residual incident light to nearby sensor pixels to enhance photon utilization.

FIG. 1C shows a schematic 130 of a polarized Bayer pattern 131 according to some embodiments of the present disclosure. The polarized Bayer pattern 131 of FIG. 1C includes four pixels that match an RGGB Bayer arrangement. Accordingly, FIG. 1C shows a red 132, green (x-polarized) 133, green (y-polarized) 134, and blue 135 Bayer arrangement, which measures 6.4 μm by 6.4 μm. Each respective pixel measures 3.2 μm by 3.2 μm. Incident light 141 from light source 140 is sorted and focused into four color-specific finite-difference time-domain pixels, with the two green pixels, 133 and 134, focusing horizontally and vertically polarized light, respectively.

The arrangement of sensor pixels of this exemplary embodiment can be altered according to the design task at hand. For example, the pattern target of FIG. 1C features a 2×2 pixel arrangement, corresponding to a distinct combination of wavelength and polarization state. At least two of the sensor pixels of each Bayer pattern target (2×2) correspond to a common color channel but different orthogonal polarization states.

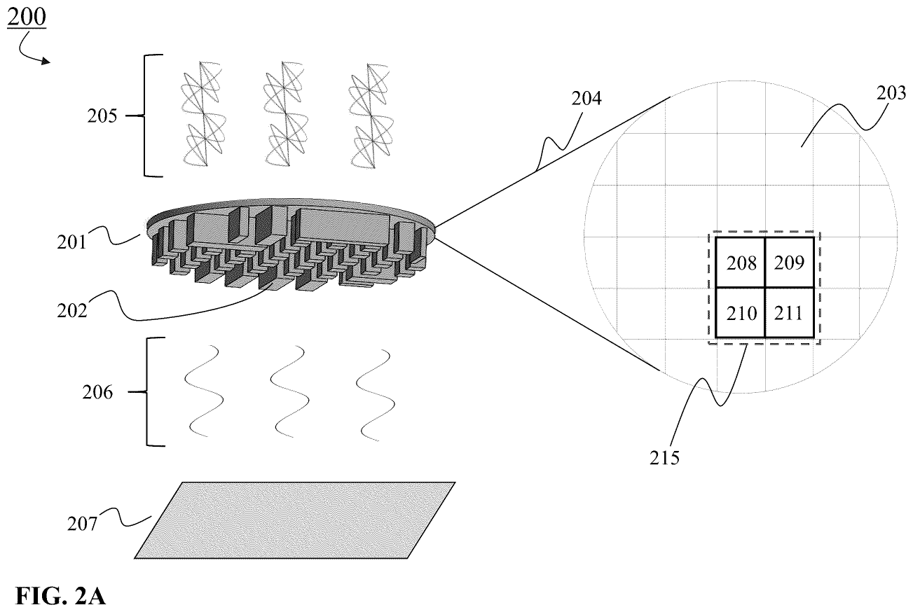

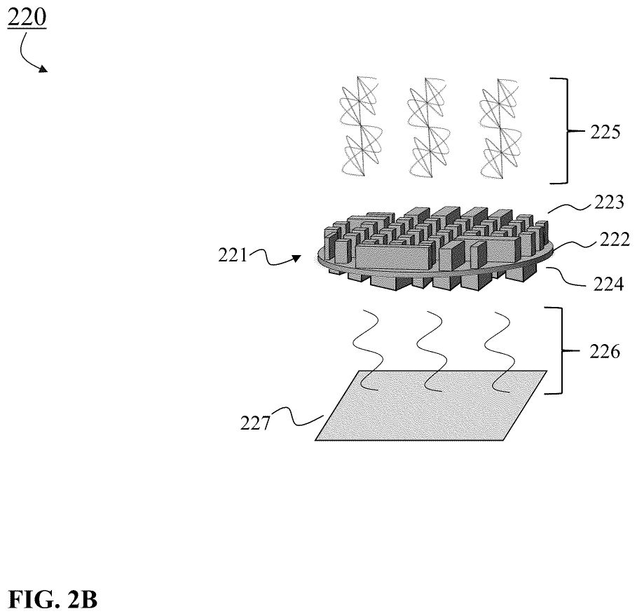

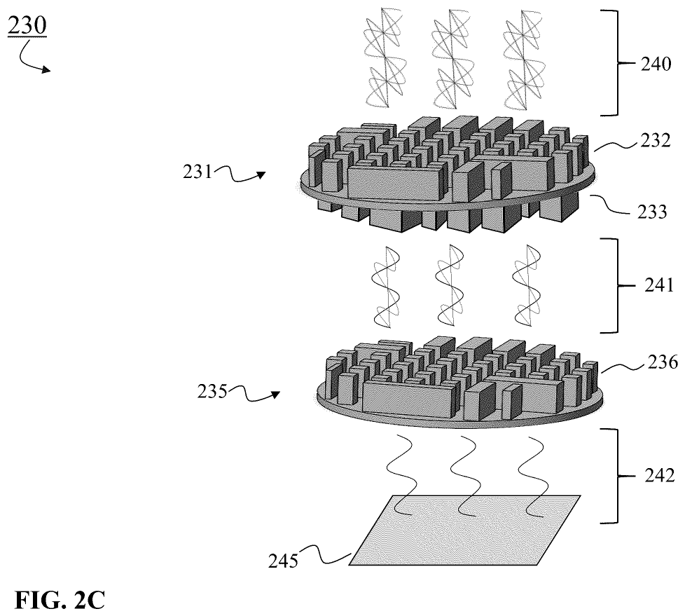

FIG. 2A shows a schematic 200 of a metalens 201 according to embodiments of the present disclosure. Nanostructures 202 are configured to form a plurality of Bayer cells 203, as visible in the top view 204 of metalens 201. The plurality of Bayer cells 203 may correspond to a plurality of Bayer patterns, as presented in FIG. 1B or FIG. 1C according to some embodiments. Furthermore, the number, design, orientation, and polarization of Bayer cells 203 can vary according to the design task at hand, as can nanostructures 202.

Incident light 205 of FIG. 2A enters metalens 201. Redirected light 206 exits metalens 201 and is accordingly distributed by desired wavelength and polarization to detector plane 207. In some embodiments, detector plane 207 can feature an image sensor comprising a plurality of photon-absorbing sensor wells, spatially aligned with the corresponding Bayer cells 203 formed by metalens 201. The sensor wells can be configured to receive redirected light 206 from Bayer cells 203 and convert the received light into digital signals encoding wavelength and polarization information of incident light 205 as transformed by metalens 201.

For instance, Bayer cell 208 of metalens 201 may be configured with nanostructures 202 to focus red light on to a corresponding sensor pixel on detector plane 207. Polarized Bayer cell 209 of metalens 201 may be configured with nanostructures 202 to focus green light of a polarization state, X for instance, on to a corresponding sensor pixel of detector plane 207. Polarized Bayer cell 210 of metalens 201 may be configured with nanostructures 202 to focus green light of an orthogonal polarization state, Y for instance, on to a corresponding sensor pixel on detector plane 207. Bayer cell 211 of metalens 201 may be configured with nanostructures 202 to focus blue light on to a corresponding sensor pixel on detector plane 207. Together, Bayer cells 208, 209, 210, and 211 can make up a Bayer unit cell 215. Bayer unit cell 215 can be repeated to cover metalens 201 or may be reconfigured according but not limited to pattern, transparency, sensitivity, polarization, number, and orientation.

FIG. 2B shows a schematic 220 of a bilayer metalens 221 according to some embodiments of the present disclosure. It is possible that the design intent of some embodiments may be such that two layers on opposite sides of substrate 222 are desirable. Such a configuration can be identified as a bilayer metalens 221. For instance, a first layer 223 can include a nanopillar topology that minimizes phase error from incoming incident light 225. A second layer 224 with a nanopillar topology can provide additional degrees of freedom for optimization according to the design task at hand. For instance, second layer 224 can correct residual errors or enhance polarization discrimination to produce redirected light 226 heading for detector plane 227. Furthermore, in the instance of the embodiment shown in FIG. 2B, the second layer 224 is also the exit layer.

FIG. 2C shows an optical configuration 230 designed for simultaneous color and polarization sorting, according to some embodiments of the present disclosure. The optical configuration 230 may be such that a bilayer metalens 231 alters incident light 240 to wavefront 241, which is directed to metalens 235. Each layer of bilayer metalens 231 may be optimized with topologies according to the design task at hand. Metalens 235 can be designed such that it provides optical configuration 230 additional degrees of freedom for optimization according to the design task at hand.

For instance, first layer 232 of bilayer metalens 231 can include a nanostructure topology that minimizes phase error from incoming incident light 240. A second layer 233 of bilayer metalens 231 can include a nanostructure topology that can correct residual error and enhance polarization discrimination to produce wavefront 241 heading for metalens 235. The first layer 236 of metalens 235 can be designed to fine-tune the overall far-field response and focus redirected light 242 to detector plane 245. Such an approach as shown in FIG. 2C can be repeated for any additional layers, each modifying incident light 240 to achieve a desired distribution on detector plane 245.

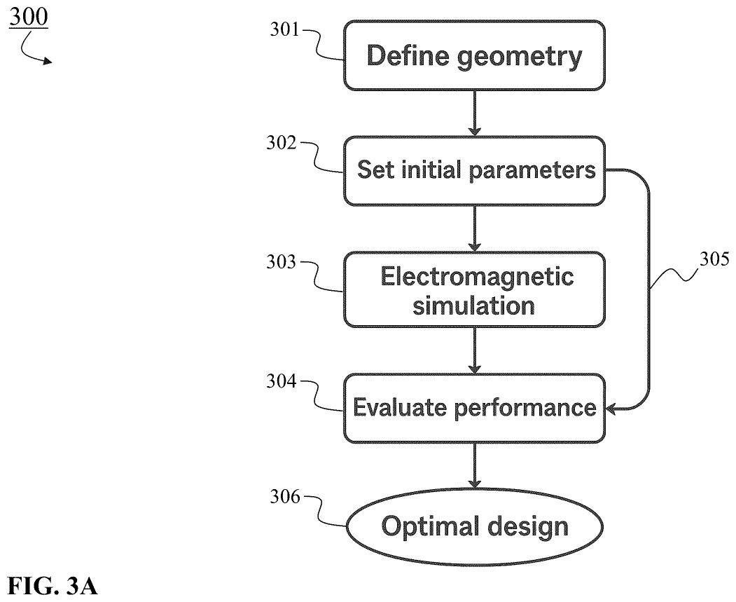

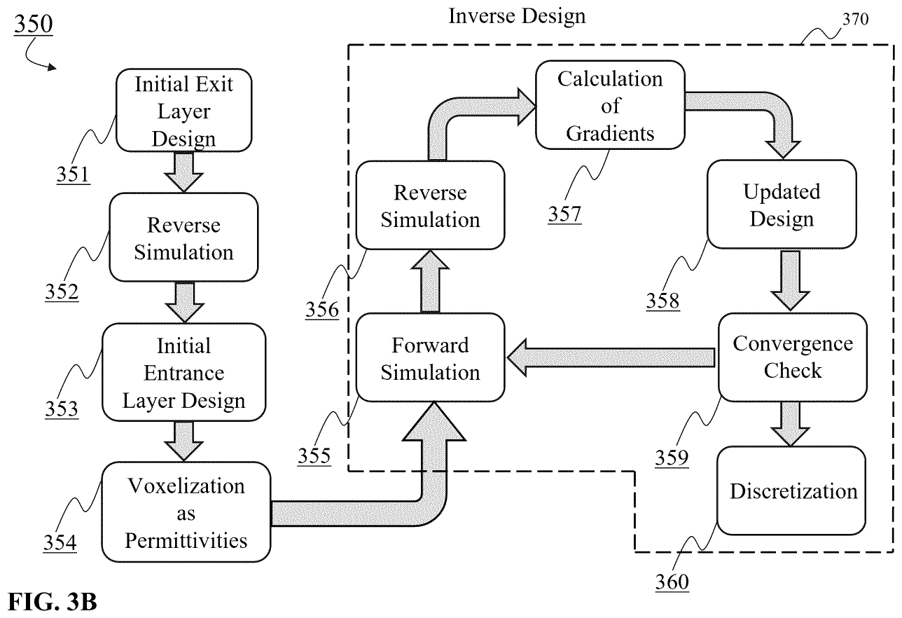

FIG. 3A shows an overview 300 of the optimization process for designing a metalens using electromagnetic simulation, according to some embodiments of the present disclosure. The process can begin with defining the geometry of the lens 301. This may involve specifying the unit cell structure, such as the shape (e.g., cylindrical, elliptical, or rectangular pillars), dimensions, spacing, and the type of substrate and materials used. Once the geometry is established, the next step is to set initial parameters 302 for the design, including the physical dimensions of the nanostructures, the refractive indices of materials, and optical performance goals such as focal length or phase delay across the aperture.

With these parameters in place, the design can then be subjected to electromagnetic simulation 303 using computational solvers like FDTD (Finite-Difference Time-Domain), FEM (Finite Element Method), or RCWA (Rigorous Coupled-Wave Analysis). These solvers can numerically evaluate how incident electromagnetic waves interact with the nanostructures and compute optical properties such as transmission, reflection, phase shift, and focusing behavior. At evaluate performance step 304, performance of the current design can then be evaluated against target specifications by analyzing metrics such as phase error, focusing efficiency, bandwidth, and polarization behavior.

If the performance is not satisfactory, the process can enter an iterative optimization loop 305, where design parameters are adjusted based on the evaluation results. This can be done manually or through automated optimization techniques like gradient descent, evolutionary algorithms, or adjoint-based methods. The modified design is then re-simulated, and its performance is re-evaluated. This loop continues until the design converges to an acceptable solution that meets all performance and fabrication criteria. In some embodiments, the result is an optimal metalens design 306 that balances electromagnetic performance with physical constraints and is ready for fabrication or further refinement.

FIG. 3B shows a diagram of an inverse design flowchart 350 according to some embodiments of the present disclosure. In FIG. 3B, an initial design 351 may begin with defining four distinct target phase profiles in the near field immediately beyond the exit layer of the metalens, with each phase profile centered in a quadrant of a metalens to match an RGGB Bayer arrangement. The quadrants can be subdivided into unit cells, typically slightly larger than one-half wavelength each, and a library can then be used to map the central phase shift in each cell to corresponding nanopillar shapes and dimensions, according to the design task at hand. This yields an initial design 351 for the exit layer in the metalens stack.

Next, simulation 352 of reverse propagation of light from focal points on the focal plane through the exit layer yields a near field phase and polarization distribution on the incident side of the exit layer. In some embodiments, the near field designates an area of 1-2 wavelengths beyond the exit layer. A second layer may be designed 353 to approximately provide this distribution from a forward light source, in the same manner as the exit layer's initial design. This can be repeated for any additional layers, each modifying the incident wavefront to better realize the target distribution at the focal plane. The designed layers are then translated 354 to permittivity values in a 3D “voxel” grid at a much finer scale, typically with each voxel two orders of magnitude smaller than a unit cell. The voxel values are spatially convolved with a local smoothing filter to soften the edges of the nanostructures, then freeform optimization may begin.

In optimization 370, forward simulation 355 evaluates focal plane intensities, and reverse simulation from steps 352 and 356 can provide residuals. This information is combined according the adjoint method to compute gradients 357 of the permittivities with regard to a figure of merit, a formula that assigns a numerical score to the distribution of light at the focal plane, and to morphological characteristics of the permittivity distribution, e.g., it penalizes structures that are too small to reliably fabricate and permittivity values that are far from those of the available fabrication materials. The permittivities are updated 358 according to the gradients, and simulations and gradients are iteratively recomputed. At convergence check 359, the norms of the focal plane intensity error and of the gradient are compared with prescribed tolerances and the cycle of optimization is repeated until the tolerances are achieved. Finally, permittivity values are clamped 360 to match those of the intended device materials and the resulting design can then be fabricated.

In some embodiments target focal plane intensity can be achieved through iterative forward simulation and gradient-based optimization. Furthermore, adjoint simulation/optimization may be used to compute gradients to update design parameters. An updated design may be used to re-initiate a cycle through forward simulation until a target focal plane intensity is achieved.

Furthermore, optimization may be achieved through an iterative loop that integrates an NLopt algorithm with an FDTD solver. Periodic boundary conditions can be applied along the metalens plane, with perfectly matched layer (PML) boundaries in the propagation direction, and the simulation covered the visible range.

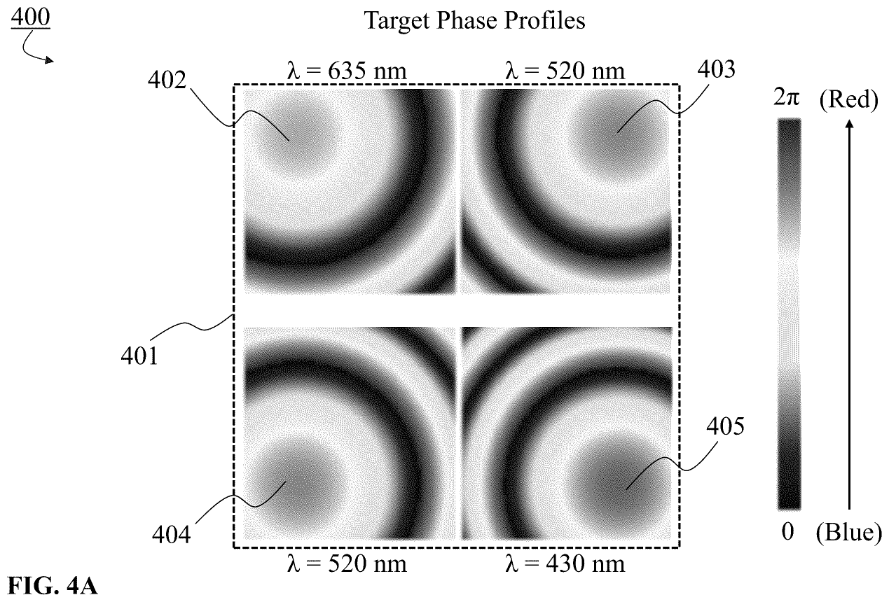

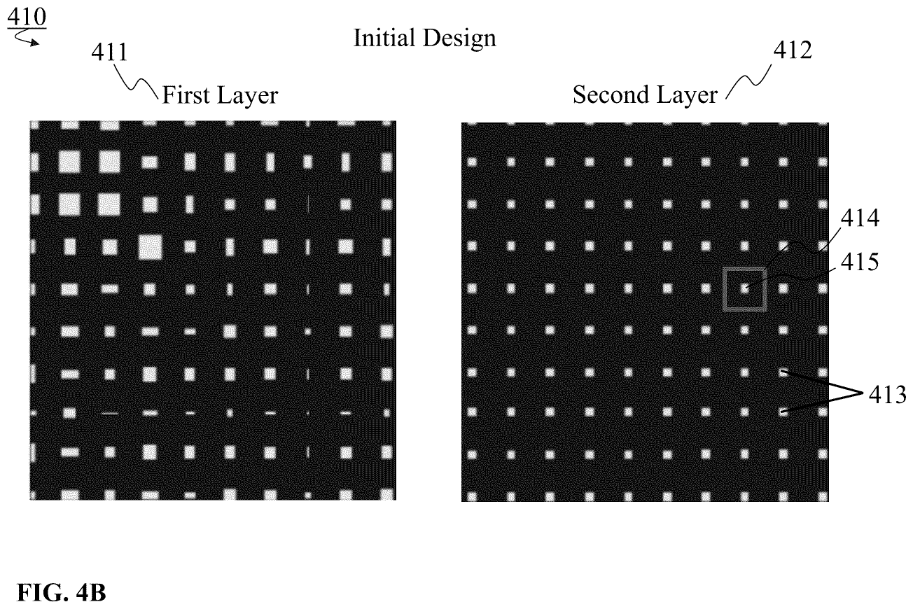

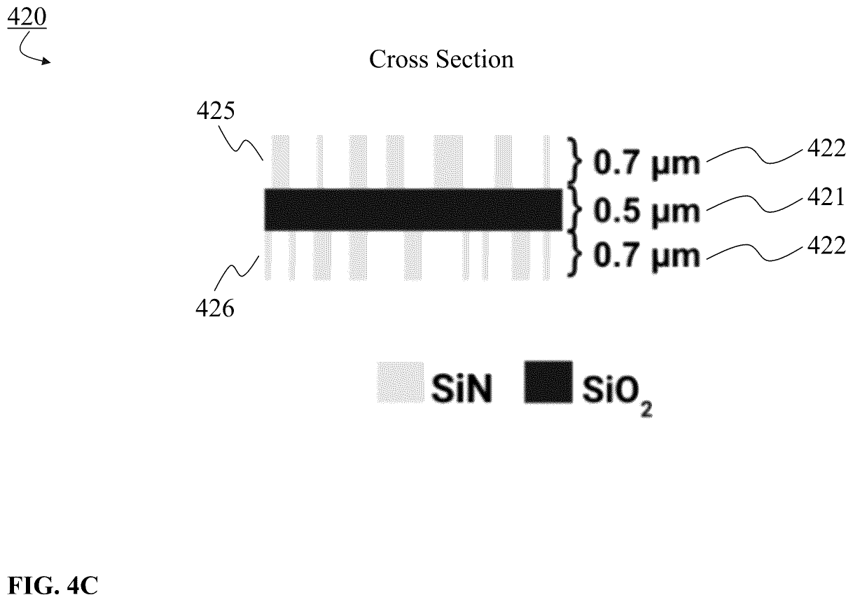

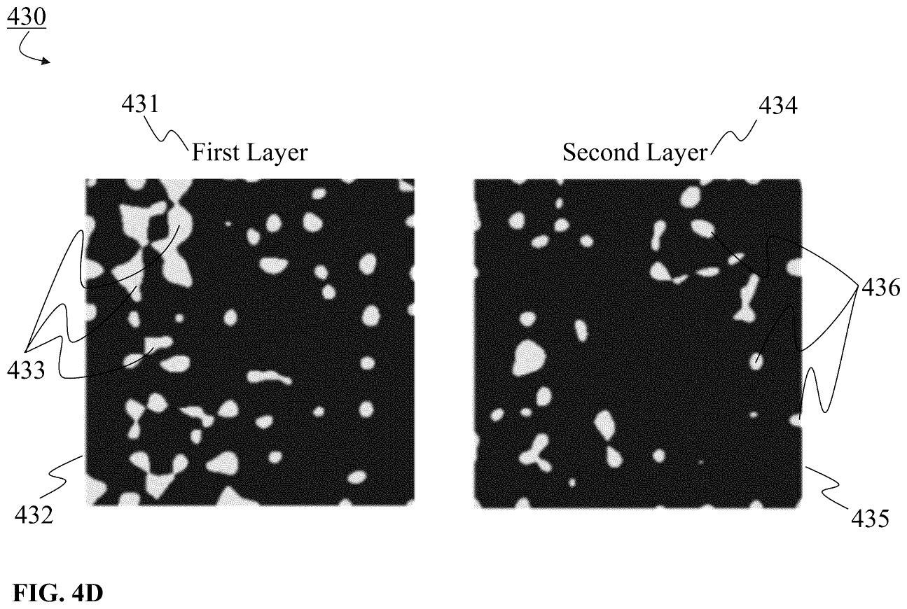

FIG. 4A shows a schematic 400 of target phase profiles for red, green, and blue according to some embodiments. Initial design can begin by defining four distinct target phase profiles, each centered in a quadrant of a Bayer unit cell 401 to match an RGGB Bayer arrangement. Quadrant 402 is designed for operation at λ=635 nm (red). Quadrant 403 is designed for operation at λ=520 nm (green), which is X-polarized. Quadrant 404 is designed for operation at λ=520 nm (green), which is Y-polarized. Quadrant 405 is designed for operation at λ=430 nm (blue).

FIG. 4B shows a schematic 410 of an initial design according to some embodiments. The first layer 411 of the initial design includes nanopillar dimensions that minimize phase error across all four target profiles. The second layer 412 starts with an arrangement of dummy nanopillars 413. Hence, FIG. 4B shows an initial configuration, optimizing the phase distribution and providing a solid starting point for optimization. Furthermore, FIG. 4B features a unit cell 414. In some embodiments a until cell 414 is a patch of the metalens that hosts a single nanopillar 415. Typically, a unit cell is slightly bigger than half of a green wavelength but can vary according to the design task at hand. In the setting of FIG. 4A, each quadrant of a Bayer unit 401 has 10×10 unit cells.

FIG. 4C shows a cross-view section 420 of an initial design according to some embodiments. The cross-view section 420 features a 0.5 μm thick SiO₂ substrate 421, and SiN nanopillars 422 with height of 0.7 μm. The first layer 425 can include nanopillar dimensions that minimize phase error across all four target profiles. The second layer 426 can start with an arrangement of dummy nanopillars, which can provide additional degrees of freedom for optimization according to the design task at hand. As shown in FIG. 2C, additional layers can be provided to the optical system to further provide additional degrees of freedom for optimization according to the design task at hand.

FIG. 4D shows a schematic 430 of optimized Bayer cells according to some embodiments of the current disclosure. Bayer cell 432 of first layer 431 features freeform nanopillars 433. Bayer cell 435 of second layer 434 features freeform nanopillars 436. The optimization process can vary from embodiment to embodiment, however in FIG. 4D resulting optimized freeform nanopillars 433 and 436 underwent 360 optimization iterations to achieve a desired outcome, such as full-color imaging.

In some embodiments, full-color imaging can be demonstrated with a virtual metalens-integrated camera sensor system.

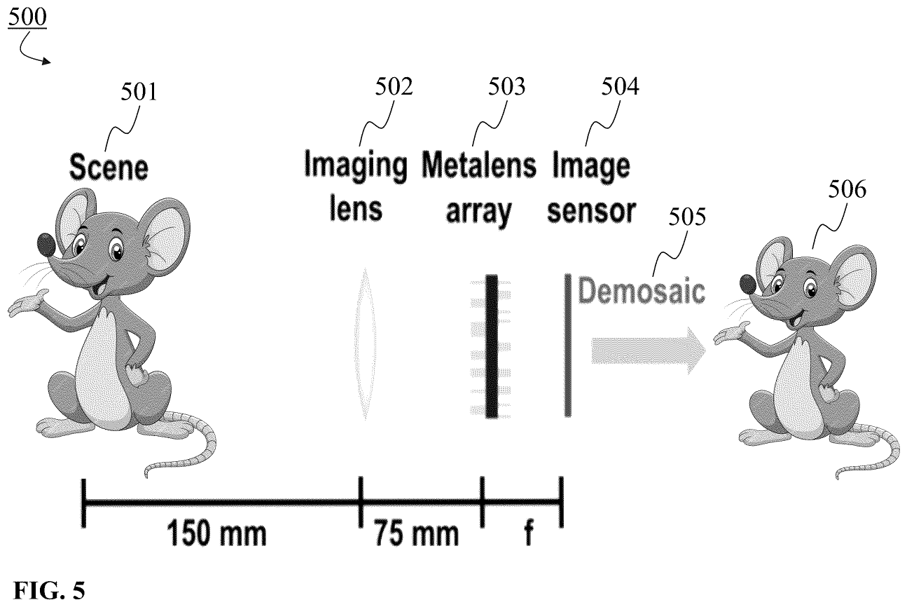

FIG. 5 shows a color imaging experimental setup 500 according to some embodiments of the current disclosure. Within the experimental setup is an imaging lens 502 positioned three focal distances from the scene 501 and the metalens array 503 placed 75 mm from the imaging lens 502. The image sensor 504 pairs with the metalens array 503, optimized with 2D Bayer cells with design weights at a focal distance of f=4 μm.

The configuration of metalens array 503 is such that it spatially directs incident light into a plurality of polarized Bayer patterns on a detector plane. In the embodiment of FIG. 5, the detector plane is an image sensor 504. Accordingly, a polarization filter array and/or Bayer filter are not necessary within color imaging experimental setup 500. In some embodiments image sensor 504 captures a raw grayscale mosaic, with each pixel corresponding to a single Bayer cell. To reconstruct three-channel color image from the grayscale RGGB Bayer image, standard demosaicing interpolation 505 can be applied for a reconstructed image 506.

Demosaicing allows for the reconstructing of a full-color image from the raw grayscale output of an image sensor, which is typically overlaid with a Bayer filter. However, in the embodiment of FIG. 5, a Bayer filter is not necessary. As a result, the raw image produced can be in the form of a single-channel grayscale mosaic where each pixel corresponds to a specific color filter, and the other two color values are missing. Demosaicing algorithms can fill in these missing color components by estimating them from neighboring pixels of the same color, effectively producing a three-channel RGB image from the incomplete input.

After demosaicing, each pixel in the image is assigned a full set of red, green, and blue values, forming the basis of the final color image. This process is crucial in digital imaging systems, enabling the transformation of a raw Bayer-patterned sensor output into a visually accurate and detailed RGB image. Using an optical system such as the one in FIG. 5 provides simultaneous high performance in color sorting and polarization sorting, without the need for additional components. Additional components can often lead to reduced image quality and information accuracy and increased computational burden for correction or enhancement. Fundamental inefficiencies, such as light loss and settings of low-light conditions or real-time applications where light throughput and compactness are at a premium can benefit from systems such as the one in FIG. 5. Ultimately, the methods of FIG. 5 provide a more robust and efficient system.

The exemplary configuration of FIG. 5 is such that the metalens may alternatively be configured for use in an optical emitter system. The optical emitter system may be configured such that incident light is structured to emit beams having prescribed wavelength and polarization characteristics corresponding to layout a plurality of spatially distinct polarized Bayer patterns.

### Performance

The performance of some embodiments can be achieved by virtually measuring the focal plane intensity of a single pixel under collimated white beam illumination.

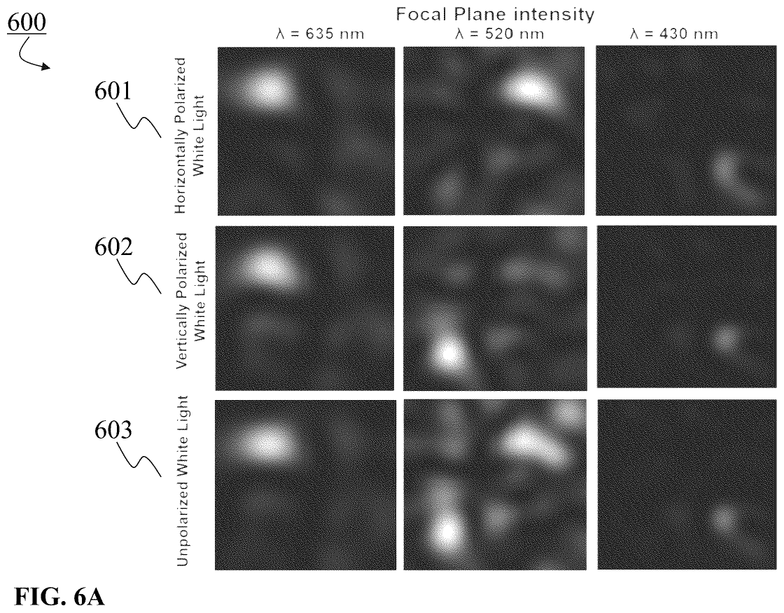

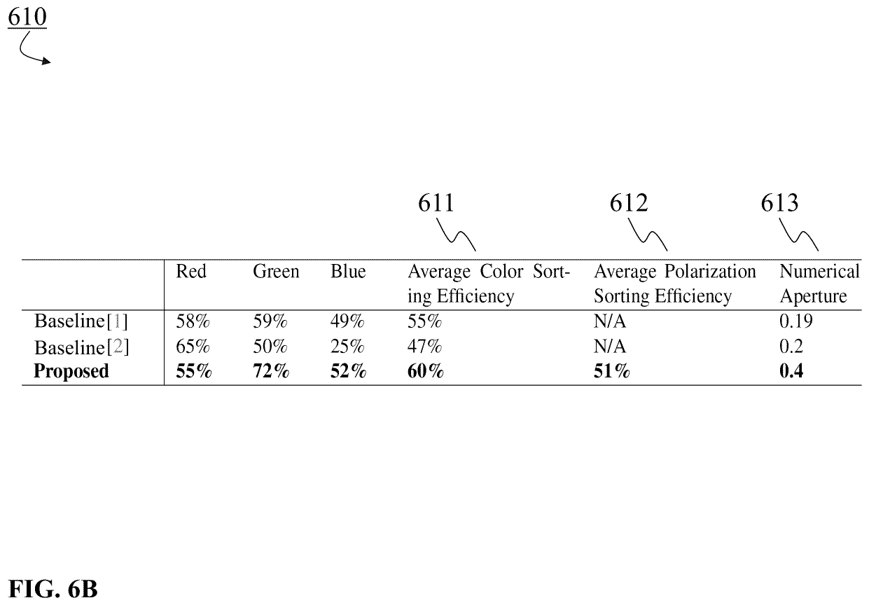

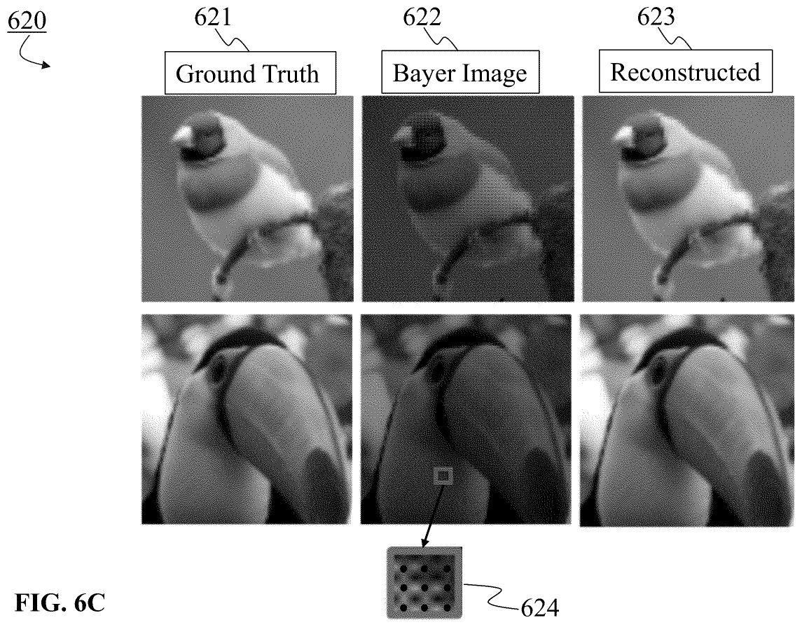

FIG. 6A shows various focal plane intensities 600 for a pixel illuminated by white light, according to some embodiments of the present disclosure. More specifically, FIG. 6 shows the pixel's focal plane intensity distributions at 635 nm, 520 nm, and 430 nm under horizontally polarized light 601, vertically polarized light 602, and unpolarized white light 603. Comparing horizontal 601 and vertical polarizations 602 reveals similar spot locations and shapes, indicating that the design is polarization insensitive. This is particularly useful in real-world applications such as general-purpose imaging and virtual reality optics. However, depending on design intent, the metalens could be designed and optimized for a polarization sensitive setting such as polarimetric imaging or sensing.

FIG. 6B shows a table 610 that summarizes a comparison of baseline metalenses to a proposed metalens, according to some embodiments of the present disclosure. The color sorting performance of the proposed and baseline metalenses can be evaluated by color sorting efficiency, the ratio of power collected in each color quadrant to the total incident power on the unit cell for a given wavelength.

The color sorting efficiencies of the proposed metalens at 635 nm (red), 520 nm (green), and 430 nm (blue) are 55%, 72%, and 52%, respectively, significantly outperforming baseline approaches. The average color-sorting efficiency 611 of a metalens designed according to some embodiments of the present disclosure is accordingly 60%. Polarization sorting efficiency can be defined as the ratio of correctly sorted polarized light power to the total incident power on the unit cell for a given wavelength. The average polarization sorting efficiency 612 of the proposed metalens is 51%, which is superior to that of leading polarization imaging metalenses. The proposed metalens is capable of simultaneously achieving superior polarization and color sorting efficiency. Lastly, the proposed metalens achieved a numerical aperture 613 of 0.4, indicating better resolution and more efficient focusing.

Furthermore, the performance of some embodiments of the present disclosure can be evaluated according to their imaging. Image performance can be evaluated across the visible spectrum by using sample scenes and measuring each pixel's Bayer spectral response with the metalens array of some embodiments. The image sensor captures a raw grayscale mosaic, with each pixel corresponding to a single Bayer cell. To reconstruct three-channel color image from the grayscale RGGB Bayer image, standard demosaicing interpolation can be applied.

FIG. 6C shows a schematic of the full-color imaging of a metalens according to some embodiments of the present disclosure. The left column shows ground truth images 621, the middle shows RGGB Bayer images 622 by spectral response, and the right shows reconstructed images 623. Ground truth images 621 contain original high-resolution color images, which may serve as reference standards. Bayer images 622 display raw output from an image sensor, where each pixel typically captures a single color (red, green, or blue). Traditional systems would require a Bayer color filter array. Reconstructed images 623 show the output after applying a demosaicing algorithm, which can estimate missing color components at each pixel by interpolating from neighboring values.

The Bayer image of the toucan includes a detailed pixel-level view of the RGGB Bayer pattern 624, visualizing how individual color samples are arranged. Ultimately, FIG. 6C demonstrates the high-fidelity color reconstruction of the metalens array of some embodiments of the present disclosure.

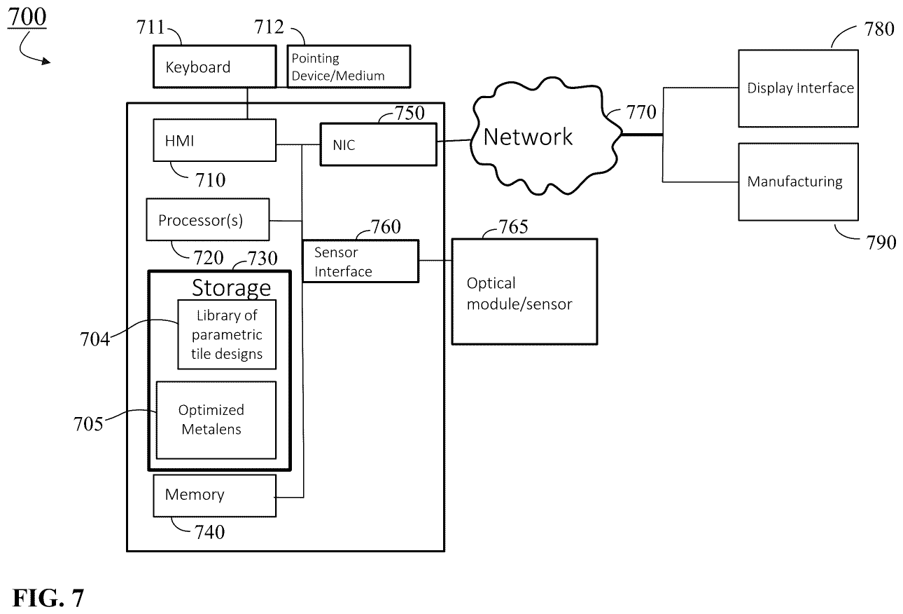

FIG. 7 shows an example configuration of a computing module 700 according to embodiments of the present disclosure. Computing module 700 may include a human machine interface (HMI) 710 connectable with a keyboard 711 and a pointing device/medium 712, one or more processors 720, a storage device 730, a memory 740, a network interface controller 750 (NIC) connectable with a network 770 including local area networks, wireless networks and internet network, a sensor interface 760 connected to an optical module/sensor 765.

The memory 740 may be one or more memory units, operating with the storage 730 that stores computer executable programs (algorithm codes) for selecting a nanopillar topology from the library of parametric tile designs 704 in connection with the processor 720. The NIC 750 includes a receiver and transmitter that can connect to the network 770 via wired-networks and via wireless-networks. After the computing module 700 executes optimization the resulting metalens 705 can be kept in storage 730 by use of the processor 720 and memory 740. Storage 730 may include a library of parametric designs 704 and/or optimized metalenses 705. The memory 740 and the storage device 730 may be referred to as a memory for convenience. Upon completion of optimization, any optimized metalens 705 contained in storage 730 may be uploaded through NIC 750 to a given network 770, which may feature wired or wireless communication links. Any optimized metalens may then be projected on a display interface 780 or transferred for manufacturing 790.

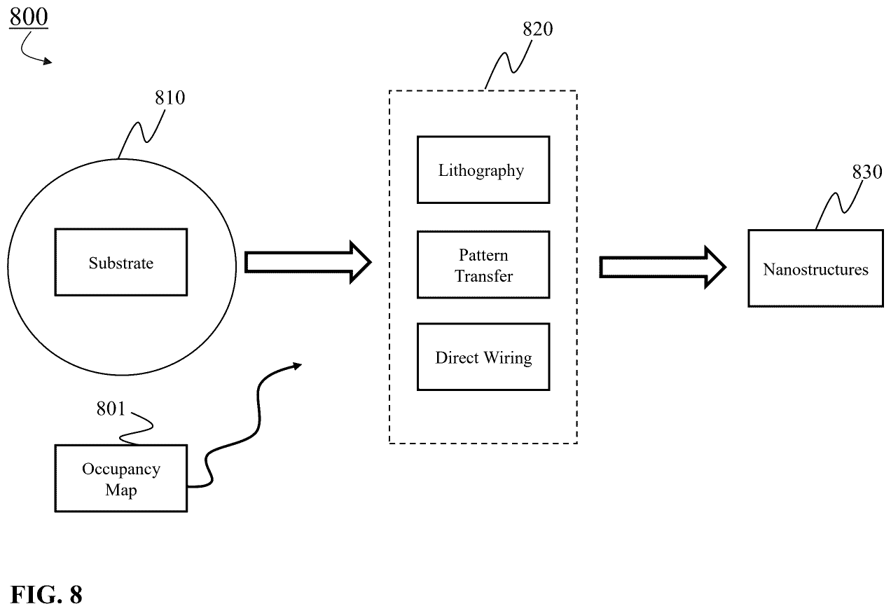

FIG. 8 shows a diagram 800 illustrating an overview of the manufacturing process relative to an optimized metalens design as an occupancy map 801, which guides methods of metalens fabrication 820 according to some embodiments. The process begins by choosing an appropriate substrate 810 material for the design task at hand. Substrates 810 used in metasurface fabrication can vary based on the method and application. Common materials include dielectric substrates, silicon, glass, and flexible polymers like PDMS (polydimethylsiloxane). Substrate 810 and occupancy map 801 further allow for manufacturing to continue to fabrication. Occupancy map 801 can provide a binary or grayscale layout that defines which regions of each unit cell or subwavelength area are “occupied” by material versus those that are left as air or substrate. It may serve as a geometric blueprint for nanostructure fabrication in inverse-designed or freeform-optimized metasurfaces.

Some exemplar methods of metalens fabrication 820 are lithography, pattern transfer, and direct wiring. Electron-Beam Lithography (EBL) uses a focused beam of electrons to write custom patterns on a resist-covered substrate with high precision. EBL is a slow process but is suitable for research and small-scale production due to its high resolution. Photolithography on the other hand is suitable for mass production because of its lower resolution and is achieved by using light to transfer a geometric pattern from a photomask to a light-sensitive chemical photoresist on the substrate.

Nano-Imprint Lithography (NIL) is a pattern transfer method that involves pressing a mold with nanoscale features into a polymer layer on a substrate. The process is followed by curing and mold removal, transferring the pattern. This method is cost-effective and suitable for high-throughput manufacturing, but it's limited by lower aspect ratios and potential defects.

Two-Photon Polymerization (TPP) is a direct wiring method that utilizes a femtosecond laser to induce polymerization in a photosensitive material, enabling the creation of complex 3D structures at the nanoscale. TPP offers high resolution and flexibility in design but is slower and more suitable for prototyping and low-volume production.

Although fabrication is not limited to these methods, all three of the described metalens fabrication processes 820 can manufacture nanostructures 830. The optimization process that produces a metalens topology can be integrated with any of the fabrication methods 820, providing incentive to deliver a higher efficiency system according to methods of the present disclosure.

### Optimization Exemplary Embodiment

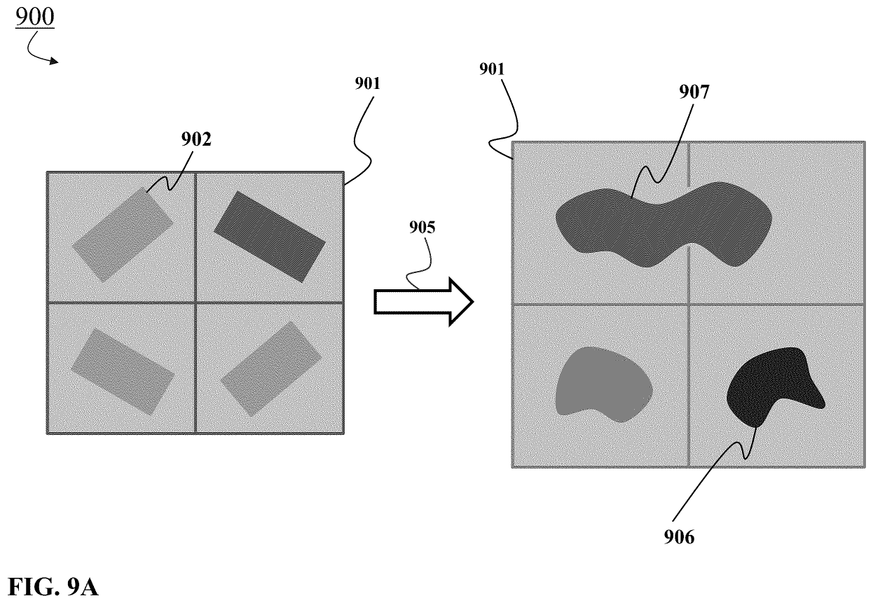

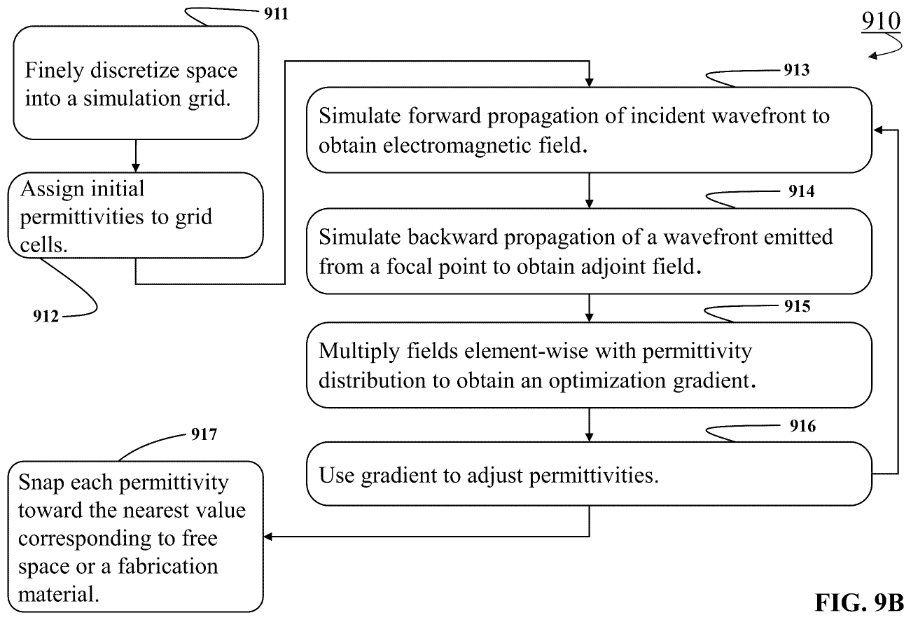

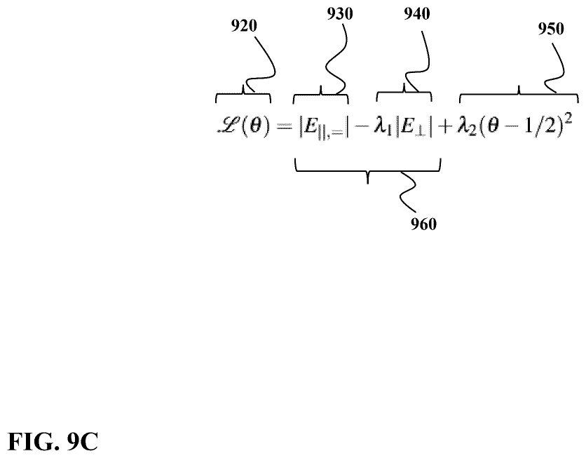

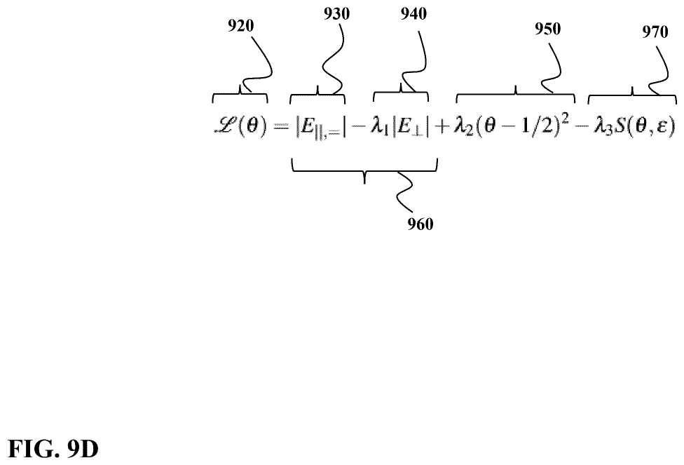

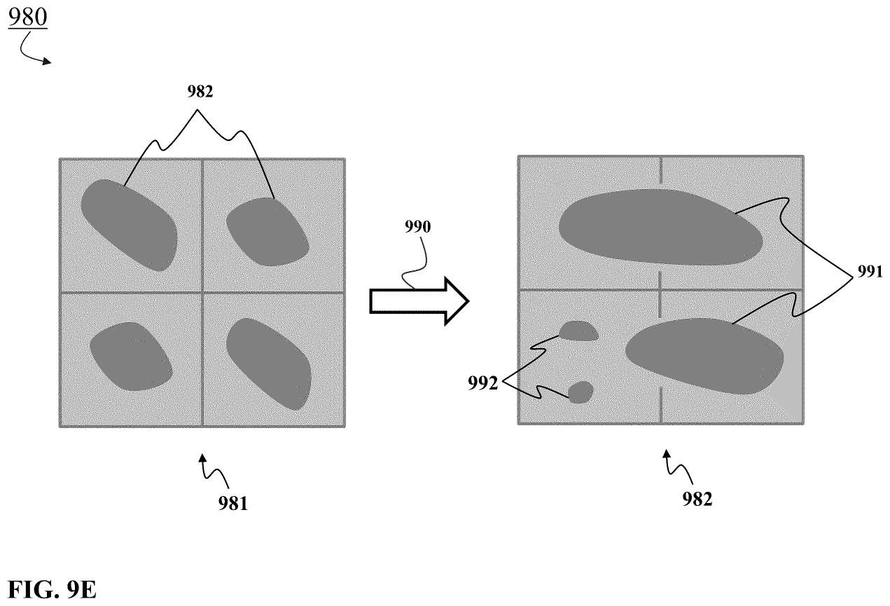

FIG. 9A shows a schematic 900 of a patch of metalens, before and after freeform optimization, according to embodiments of the present disclosure. When the nanopillar topology is optimized a design task such as energy spill reduction, the result of optimization would be freeform nanostructures formed by merging shapes of at least two nanopillars in neighboring unit cells. Metalens patch 901 features four unit cells (quadrants), each with a nanopillar 902. After optimization 905, the top view patch 901 of a metalens includes an irregularly shaped nanopillar 906 formed by modifying the original shape of nanopillar 902 in the bottom right quadrant. Furthermore, nanostructure 907 was formed by modifying and merging nanopillars 902 in the top two quadrants of metalens patch 901.

FIG. 9B shows a flowchart 910 with steps involved in optimizing freeform design, according to some embodiments of the present disclosure. The space may be discretized 911 into a fine 3D grid, typically 5 nanometer resolution, and each grid element is assigned a permittivity 912, usually corresponding to the distribution of free space and solid material in the initial nano-pillar design. The adjoint method can be used to calculate the gradient of the performance objective with regard to the permittivities, as follows: The electromagnetic field induced by forward propagation of the incident wavefront through the device is obtained by solving Maxwell's equations 913. The electric field at a desired focal point is extracted from this solution, and the electromagnetic field induced by propagating that field backward from the focal point is obtained by solving Maxwell's equations 914. These forward field, permittivity field, and adjoint field are multiplied 915 element-wise to obtain the gradient of the focal term in the objective. The gradients of the spill terms are calculated the same way, but for other focal points. The gradients of the binarization and ease-of-fabrication terms are calculated algebraically from the permittivity distribution. Finally, all gradients are added and the result is used to adjust the permittivities 916. This repeats until the value of the objective reaches a satisfactory threshold or it ceases to improve. Then each permittivity value is snapped 917 to the nearest value of a fabrication material or free space.

FIG. 9C shows a schematic of an optimization problem solved by some embodiments to improve the focal efficiency of a metalens with freeform topology. In this embodiment, the cost function 920 is probabilistic such that the optimization of this cost function provides a field θ of probabilities where θ_{xy}=1 if the matter is to be deposited on the substrate at (x,y) and θ_{xy}=0 if not. An occupancy map allows to design a topology of various complexities to achieve the desired focal efficiency, while the probabilistic estimation of the occupancy map allows to consider variations of the topologies achieving similar objectives. Furthermore, the occupancy map contains parameters regarding position and orientation of the metalens topology as well as details of optimization.

To that end, the cost function includes energy term 960 designed to increase the focal efficiency and reduce the energy spill, and optional binarization term 950 which encourages occupancy values near 0 and 1. In some implementations, the energy term 960 includes a focal efficiency term 930 representing the total energy correctly delivered to the vertically polarized focal point when the metalens is illuminated with a plane wave and a spill term 940 representing the total energy of vertically polarized light incorrectly delivered to the horizontally polarized imaging area (and vice versa).

Although maximizing the focal efficiency term 930 implies minimizing the spill term 940, it does not necessarily play out that way in optimization. 100% efficiency is unattainable for physical reasons, so the term 930 may plateau before all spill is resolved. The second term 940 serves to “push” away the light that is incorrectly scattered to the wrong target zone on the sensor. Much of this incorrectly scattered light is moved to the correct target zone, where the first term then nudges it to the appropriate focal point. Some of the incorrectly scattered light is pushed off the sensor entirely and lost, but in doing so the noise in the polarization sorting is reduced, which is advantageous for the subsequent comparison of sensor values for scene reconstruction.

FIG. 9D shows a schematic of an optimization problem solved by some embodiments to improve the focal efficiency of a metalens topology according to some embodiments of the present disclosure. In this embodiment, optimization of cost function 920 is achieved by incorporating the morphology term 970. Morphology term 970 is a penalty assessed to structural features (islands, holes, bridges, ravines) that are too small to be made with current fabrication technology, as is discussed in the description for FIG. 3B.

The morphology term 970 is computed by convolving the occupancy field θ with a center-surround kernel (e.g., Laplacian-of-Gaussian or Ricker wavelet) that is tuned to highlight gaps and blobs that are too small to fabricate (e.g., less than 40 nm in at least one direction). Minimizing the squared difference between the filter response and the occupancy values tends to erode blobs and fill gaps that are smaller than the target size, while the structure boundaries are still being tuned by the focal efficiency terms.

In some embodiments the morphology term 970 is kept inactive (λ₃=0) until optimization of the first two terms, focal efficiency 930 and spill 940, plateaus. Ultimately, the morphology term 970 is activated with a rising λ₃>0 and the optimization proceeds a few more iterations to clean up non-fabricable features.

FIG. 9E shows a schematic 980 of a patch of metalens before and after optimization 990 according to an embodiment of the present disclosure. The initial patch of metalens 981 contains irregularly shaped nanopillars 982 arranged throughout square unit cells. In some embodiments, the irregularly shaped nanopillars 982 can have convex properties. In this embodiment of the present disclosure, optimization 990 generates nanostructures 991 and shapes 992. The dimensions of shapes 992 are less than a threshold and thus are too small to fabricate. The morphology term 970 of the optimization function suggests eroding shapes 992 in foresight of manufacturing. In this instance, nanostructures 991 have dimensions greater than a threshold and are kept intact for fabrication.

### Exemplar Design Embodiment: Designing a Metalens for Far-Field Polarization

This exemplary embodiment is provided for illustrational purposes without intending to limit the scope of various embodiments of the present disclosure.

In this exemplar embodiment, the design is optimized by discretizing the metalens surface into a real-valued occupancy array θᵢⱼ∈[0,1] at 5 nm pitch, and computing the gradients of the figure of merit with respect to array θ via the adjoint method. This requires two full simulations of wave propagation through the device. At present, whole-device gradients are impractical because one iteration may takes two days on a computer cluster. Given suitably structured initial conditions, some embodiments allow the problem to be partitioned into 4λ×4λ-domains that overlap by λ/2 at their edges, such that each domain can be independently optimized with negligible inconsistency at the edges. A trial introduction of an edge-consistency term into the figure of merit does not necessarily alter the course of the optimization nor its final result.

In some embodiments open-source simulator MEEP can obtain near-field information from Rigorous Coupled-Wave Analysis (RCWA), a Raleigh propagator can obtain far-field intensities, the adjoint method may compute gradients with respect to a figure of merit, and the Method of Moving Asymptotes (MMA) optimizes. MMA constructs a convex separable proxy function from recent gradient samples; this function is easy to optimize and, under modest regularity conditions, can be considered a lower bound on the figure of merit.

The discovery of the following interventions improve both optimization speed and results: The initial field is “softened” to non-binary values via Gaussian convolution to prevent lock-in. Every 5 iterations the field is averaged with its own binarization, which accelerates the solidification of the interiors of structures. The morphology term is kept inactive (λ₃=0) until optimization of the first two terms plateaus. It is then activated with a rising λ₃>0 and the optimization proceeds a few more iterations to clean up non-fabricable features.

### Initial Conditions

In some embodiments, initialization begins with a 40 μm ×20 μm surface and an aim to focus a 532 nm plane wave two images to two points 20 μm apart at a distance of 33 μm. A single layer freeform metalens is voxelated at 10 nm pitch yielding an optimization problem with 8×106 binary variables, which is relaxed to continuous variables in [0,1].

Since gradient ascent in the figure of merit can only guarantee convergence to a local optimum, a favorable initialization plays a large role in the quality of the final result. Initialization allows starting design with a high-efficiency nanopillar design in which the planar dimensions of rectangular nanopillars have been pre-optimized for far-field focal efficiency. Then the substrate may be partitioned into cellular arrangements: a square grid; a hexagonal grid; or a bipolar grid where nanopillars are arranged on iso-phase delay contours of the two (horizontal and vertical) focal points. In some embodiments, the bipolar arrangement provided the highest focal efficiency, but only in zones on the metasurface where the pillar density was ≈0.4λ. The square and hexagonal arrangements provided nearly equal efficiency.

Typically, hexagonal arrangements are more efficient, but in our setting the hexagonal arrangement was more prone to unwanted cross-polarization spill. Some embodiments call for hybrid cellular arrangements, one of which being a bipolar grid in zones where it is dense with a square grid elsewhere.

In some embodiments, a square grid proved to be most favorable to this process, leading to highest focal efficiency and lowest cross-polarization spill. Furthermore, optimizing all patches independently and stitching together the results may yield a metalens with improved focal efficiency.

The above description provides exemplary embodiments only, and is not intended to limit the scope, applicability, or configuration of the disclosure. Rather, the above description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the above description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a FIG. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments. Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

We claim:

1. A metalens comprising one or more layers of subwavelength nanostructures configured to redirect incident light onto a detector plane in a plurality of spatially distinct polarized Bayer patterns,
wherein each polarized Bayer pattern comprises at least four sensor pixels, each corresponding to a distinct combination of wavelength band and polarization state,
and wherein at least two of the sensor pixels within each polarized Bayer pattern correspond to a common wavelength band but orthogonal linear polarization states.

2. The metalens of claim 1,
wherein each polarized Bayer pattern comprises four spatially distinct regions, each configured to redirect the incident light of a specified wavelength band and polarization state onto a corresponding sensor pixel on the detector plane, the four regions comprising:
a first region configured to redirect red light onto a first sensor pixel;
a second region configured to redirect blue light onto a second sensor pixel;
a third region configured to redirect green light having a first polarization state onto a third sensor pixel; and
a fourth region configured to redirect green light having a second polarization state, orthogonal to the first polarization state, onto a fourth sensor pixel.

3. The metalens of claim 2, wherein each polarized Bayer pattern is repeated to cover an image sensor.

4. The metalens of claim 2, wherein each of the regions is further configured to redirect residual incident light to nearby sensor pixels to enhance photon utilization.

5. An optical structure comprising:
the metalens of claim 1, wherein the nanostructures are configured to form a plurality of Bayer cells corresponding to the plurality of polarized Bayer patterns; and
an image sensor comprising a plurality of photon-absorbing sensor wells defining the detector plane and spatially aligned with the corresponding polarized Bayer cells formed by the metalens,
wherein the sensor wells are configured to receive light redirected by the Bayer cells and to convert the received light into digital signals encoding wavelength and polarization information of the incident light as transformed by the metalens.

6. The metalens of claim 1, wherein the metalens comprises two layers of subwavelength nanostructures forming a bilayer metalens.

7. The metalens of claim 6, wherein the nanostructures in at least one of the layers are freeform in geometry.

8. The metalens of claim 6, wherein the metalens is inverse-designed using electromagnetic simulation and gradient-based optimization.

9. The metalens of claim 8, wherein the electromagnetic simulation comprises Finite-Difference Time-Domain (FDTD) modeling and the optimization includes adjoint-based gradient computation.

10. The bilayer metalens of claim 6, comprising:
a first layer comprising a plurality of subwavelength nanostructures configured to at least partially sort incident light by wavelength band and polarization state; and
a second layer comprising a plurality of subwavelength nanostructures configured to modify an optical response of the first layer such that a combined optical response of the bilayer metalens redirects the incident light onto the detector plane in the plurality of spatially distinct polarized Bayer patterns.

11. The bilayer metalens of claim 10, wherein a first layer is optimized to approximate a target far-field phase response and a second layer is optimized to compensate for residual optical errors of the first layer.

12. The bilayer metalens of claim 10, wherein the nanostructures are fabricated on a dielectric substrate, and have features smaller than the wavelength of visible light.

13. The bilayer metalens of claim 12, wherein the first layer and the second layer are formed on opposite sides of the dielectric substrate, and wherein the nanostructures in the first layer and the second layer are oriented in opposite directions relative to the propagation direction of incident light.

14. The metalens of claim 1, wherein the metalens is integrated into an optical system comprising an image sensor, and wherein the metalens is configured to redirect incident light, sorted by wavelength band and polarization state, onto spatially distinct regions of the sensor to enable single-exposure acquisition of color- and polarization-resolved images.

15. The metalens of claim 1,
wherein the metalens is configured for use in an optical emitter system,
such that incident light is structured to emit beams having prescribed wavelength and polarization characteristics corresponding to layout of a plurality of spatially distinct polarized Bayer patterns.

16. A multilayer metalens comprising:
a first layer comprising a plurality of subwavelength nanostructures configured to at least partially sort incident light by wavelength band and polarization state; and
a second layer comprising a plurality of subwavelength nanostructures configured to modify the optical response of the first layer such that a combined optical response of the multilayer metalens redirects the incident light onto a detector plane with spatial separation of different wavelength bands and polarization states to form a plurality of spatially distinct polarized Bayer patterns,
wherein each polarized Bayer pattern comprises at least four sensor pixels, each corresponding to a distinct combination of wavelength band and polarization state, and wherein at least two of the sensor pixels within each polarized Bayer pattern correspond to a common wavelength band but orthogonal linear polarization states.

17. A method of designing the multilayer metalens of claim 16 to perform an optical task, the method comprising:
determining a target far-field optical response corresponding to the optical task;
optimizing a first layer of subwavelength nanostructures to approximate the target far-field response using electromagnetic simulation and gradient-based optimization;
computing a residual optical error between the optical response of the first layer and the target far-field response;
optimizing a second layer of subwavelength nanostructures to compensate for the residual optical error; and
jointly refining the nanostructures in both the first and second layers to improve optical efficiency and reduce crosstalk between output channels.

18. The method of claim 17, wherein the electromagnetic simulation comprises Finite-Difference Time-Domain (FDTD) modeling and the optimization uses adjoint sensitivity analysis.

19. The method of claim 17,
wherein the target far-field optical response is defined to replicate an RGGB polarized Bayer pattern comprising at least four sensor pixels, each corresponding to a distinct combination of wavelength band and polarization state,
wherein at least two of the sensor pixels correspond to a common wavelength band but orthogonal polarization states.

20. The method of claim 17, further comprising fabricating the first and second layers on opposite sides of a shared dielectric substrate, such that the nanostructures are oriented in opposite directions along the propagation axis of incident light.

21. The method of claim 17, wherein the optical task includes configuring the bilayer metalens to operate in conjunction with an image sensor or light source within an optical system includes one or a combination of a camera, a polarimetric imager, a display device, a structured light projector, and an optical communication system.
